(19) United States
(12) Patent Application Publication
(10) Pub. No.: US 2025/0010732 A1
(43) Pub. Date: Jan. 9, 2025

(54) AC CHARGING SYSTEM FOR CHARGING A HIGH-VOLTAGE BATTERY OF A VEHICLE

(71) Applicant: BRUSA ELEKTRONIK AG, Buchs (CH)

(72) Inventors: Ayoub SIDHOM, München (DE); Daniel BOLOHAN, Buchs (CH); Georgios SFAKIANAKIS, Buchs (CH); Martin PAVLOVSKY, München (DE)

(21) Appl. No.: 18/712,599

(22) PCT Filed: Nov. 17, 2022
(86) PCT No.: PCT/EP2022/082337

§ 371 Date: May 22, 2024

(30) Foreign Application Priority Data
Nov. 24, 2021 (CH) 070596/2021

(51) Int. Cl. B60L 53/122; B60L 53/16; B60L 53/302; H02J 7/02; H02J 50/10; H05K 7/20

(52) U.S. Cl. CPC B60L 53/122; B60L 53/16; B60L 53/302; H02J 7/02; H02J 50/10; H05K 7/20254; H05K 7/20927; B60L 2210/10; B60L 2210/30; H02J 2207/20

(57) ABSTRACT

An alternating current charging system to charge a battery of a vehicle, wherein the system comprises a socket to connect a cable and receive alternating current via the cable from a first supply and a coil to wirelessly receive alternating current from a second supply, wherein the system is configured to charge the battery in a first mode based on the current received via the cable and in a second mode based on the current wirelessly received via the coil, wherein the system comprises a first unit comprising a first component for charging in the first mode, the first unit connected to the socket, a second unit comprising a second component for charging in the second mode, the second unit connected to the coil, and a third unit comprising a third component for charging in the first mode and in the second mode, the third unit connectable to the battery.

### CROSS-REFERENCE TO RELATED APPLICATIONS

The present application is the U.S. National Phase of PCT/EP2022/082337, filed on 17 Nov. 2022, which claims priority to Swiss Patent Application No. 070596/2021, filed on 24 Nov. 2021, the entire contents of which are incorporated herein by reference.

### FIELD OF THE INVENTION

The present invention relates to a charging system configured for charging a battery electric vehicle by wire and wirelessly.

### BACKGROUND OF THE INVENTION

Batteries of electric vehicles can be charged using alternating current (AC) or direct current (DC) energy transfer. DC energy transfer is typically provided using high-power converters which are placed at dedicated charging points. While DC charging is typically faster than AC charging, it is not convenient for the end user as DC charging points are typically placed in remote areas and not installed in houses or residential areas, as the installation of a DC charging point is expensive and the preexisting network capacity in those areas is usually vulnerable.

AC charging on the other hand is very important for residential areas and (semi) public urban areas. Typical AC chargers are capable of providing a charging power of up to 22 kW. AC charging systems can be divided into wired charging systems and wireless charging systems, wherein wireless charging systems are mainly embodied as inductive charging systems (ICSs). Wired AC chargers are typically integrated in electric vehicles, and are also referred to as on-board chargers (OBCs). An ICS typically comprises two separate modules which are often referred to as ground-pad module (GPM) and car-pad module (CPM).

The GPM is installed outside the electric vehicle while the CPM is installed in the electric vehicle, usually on the bottom side of the vehicle. Electromagnetic interaction between the GPM and the CPM enables energy transfer from the GPM to the CPM, and the CPM is in turn used for charging a battery of the electric vehicle. Wireless charging systems are often more convenient for a user as typically no manual intervention is required for starting the charging process of the battery other than parking the vehicle above the GPM. Wired charging systems on the other hand require the user to connect the electric vehicle to a utility grid via a cable.

OBC are often standard components in BEVs and plugin hybrid electric vehicles. Since wireless AC charging systems are more expensive than wired AC charging systems, wireless AC charging systems are typically only offered as optional feature by car manufacturers. In case a CPM is to be integrated into an electric vehicle for wireless charging, it is often a challenge for original equipment manufacturers to find the required space in the car where the CPM can be installed as CPMs are only an optional feature.

Having both a wired charging system and a wireless charging system in the electric vehicle furthermore leads (a) to an increased mass of the vehicle and thereby to an increased energy consumption and to increased costs for the user, and (b) to a low component utilization: while the battery is charged using the wired charging system, the components in the wireless charging system are unused, and while the battery is charged using the wireless charging system, the components of the wired charging system are unused.

### Object of the Invention

It is thus an object of the present invention to provide an AC charging system having both wired charging functionality and wireless charging functionality and avoiding the above deficiencies. Specifically, an object of the present invention is to provide an AC charging system with both wired charging functionality and wireless charging functionality which is less expensive, has less mass and requires a smaller installation space than separately installed wired and wireless chargers as known from the prior art.

These objects are achieved by realizing the features of the independent claim. Features which further develop the invention in an alternative or advantageous manner are described in the dependent claims.

### SUMMARY OF THE INVENTION

The invention relates to an alternating current (AC) charging system for charging a high-voltage (HV) battery of a vehicle, wherein the AC charging system comprises a socket configured for connecting a cable and receiving AC via the cable from a first external power supply and a coil configured for receiving AC wirelessly from a second external power supply, wherein the AC charging system is configured for charging the HV battery in a first mode based on the alternating current received via the cable and charging the HV battery in a second mode based on alternating current wirelessly received via the coil, wherein the AC charging system further comprises a first unit comprising at least one first electric component exclusively usable for charging in the first mode, the first unit connected to the socket, a second unit comprising at least one second electric component exclusively usable for charging in the second mode, the second unit connected to the coil, and a third unit comprising at least one third electric component usable for charging in the first mode and for charging in the second mode, the third unit connectable to the HV battery. In particular, the first external power supply is an AC utility grid and the second external power supply is a ground-pad module (GPM) that provides electric power wirelessly.

In some embodiments, the first unit comprises a first electromagnetic compatibility (EMC) filter connected to the socket and configured for receiving the AC from the socket.

In some embodiments, the first unit comprises a power factor correction (PFC) configured for receiving AC filtered by the first EMC filter and converting it into direct current (DC) and an AC controller configured for controlling the PFC.

In some embodiments, the second unit comprises a tuning circuit configured for receiving the AC from the coil.

In some embodiments, the second unit comprises a rectifier configured for receiving AC tuned by the tuning circuit and for converting it into DC.

In some embodiments, the second unit comprises a receiver configured for receiving charging management data.

In some embodiments, the second unit comprises a sensor configured for determining sensor data relating to a magnetic field detected at the coil.

In some embodiments, the third unit comprises a DC/DC converter configured for receiving DC from the PFC and from the rectifier.

In some embodiments, the third unit comprises a second EMC filter configured for receiving the DC converted by the DC/DC converter, filtering said converted DC for supplying it to the HV battery.

In some embodiments, the third unit comprises a DC controller connected to the receiver, to the sensor, to the DC/DC converter, and to the AC controller, said DC controller configured for controlling the DC/DC converter based on at least one of the charging management data, the sensor data, and AC controller data received from the AC controller.

In some embodiments, the first unit, the second unit, and the third unit are comprised by one single housing.

In some embodiments, the first unit and the third unit are comprised by a first housing and the second unit is comprised by a second housing, wherein the AC charging system further comprises one of: (a) a cooling unit with a cooling plate having a first cooling plate surface and a second cooling plate surface, the first cooling plate surface abutting the first housing and the second cooling plate surface abutting the second housing, and (b) a cooling unit with a first cooling plate and a second cooling plate, the first cooling plate abutting the first housing and the second cooling plate abutting the second housing, the first cooling plate and the second cooling plate sharing a single coolant circuit.

In some embodiments, a cooling unit is a water-cooled cooling unit.

In some embodiments, a cooling unit is an air-cooled cooling unit.

In some embodiments, at least two of the first unit, the second unit and the third unit are parts of one cooling system common to the at least two units.

In some embodiments, the first housing comprises a first cooling system for cooling the first housing, and the second housing comprises a second cooling system for cooling the second housing.

In some embodiments, the first housing and the second housing comprise one cooling system common to the two housings.

In some embodiments, the first unit, the second unit, and the rectifier from the third unit are comprised by a first housing, and the third unit except for the rectifier is comprised by a second housing.

The invention further relates to a module for an alternating current (AC) charging system for charging a high-voltage (HV) battery of a vehicle, wherein the module comprises a first electromagnetic compatibility (EMC) filter configured for receiving the AC from a socket, a power factor correction (PFC) configured for receiving AC filtered by the first EMC filter and converting it to direct current (DC), an AC controller configured for controlling the PFC, a first interface, a DC/DC converter configured for receiving DC from the PFC and from the first interface, a second interface, a DC controller configured for receiving sensor data and charging management data from the second interface, receiving AC controller data from the AC controller, and controlling the DC/DC converter based on at least one of the charging management data, the sensor data, and the AC controller data, a second EMC filter configured for receiving DC converted by the DC/DC converter, a third interface configured for receiving DC filtered by the second EMC for supplying it to the HV battery. In other words, i.e., making use of the description above, this subject-matter can also be defined in that the first unit and the third unit form a first module comprising, and surrounded by, a first housing. In this case, as a separate subject-matter, the second unit forms a second module comprising, and surrounded by, a second housing.

The invention further relates to a module for an alternating current (AC) charging system for charging a high-voltage (HV) battery of a vehicle, wherein the module comprises a tuning circuit configured for receiving AC from a coil, a rectifier configured for receiving AC tuned by the tuning circuit, a receiver configured for receiving charging management data, a sensor configured for determining sensor data relating to a magnetic field detected at the coil, a first interface, a direct current/direct current (DC/DC) converter configured for receiving DC from the rectifier and from the first interface, a second interface, a DC controller configured for receiving the sensor data and the charging management data, receiving AC controller data from the second interface, and controlling the DC/DC converter based on at least one of the charging management data, the sensor data, and the AC controller data, an electromagnetic compatibility (EMC) filter configured for receiving DC converted by the DC/DC converter, and a third interface configured for receiving DC filtered by the EMC for supplying it to the HV battery. In other words, i.e., making use of the description above, this subject-matter can also be defined in that the second unit and the third unit form a first module comprising, and surrounded by, a first housing. In this case, as a separate subject-matter, the first unit forms a second module comprising, and surrounded by, a second housing.

In yet other words, preferred embodiments provide common electric components, such as a DC/DC converter stage and a EMC filter stage, that can be used by both the wired charging mode and the wireless charging mode. Using such shared parts enables the construction of an AC charging system having both wired and wireless charging functionality which has a reduced number of components compared to state-of-the-art solutions as some components are jointly utilized by both wired and wireless charging functionality. Specifically, the DC/DC functionality is integrated into a single isolated DC/DC converter.

In particular, said first unit is configured to convert AC grid voltage obtained from a utility grid to an unregulated fixed DC voltage. High-frequency AC voltage obtained via the second unit after the tuning circuit stage is, in particular, rectified to a fixed DC voltage as well. The first unit and the second unit may be electrically connected to a DC-link capacitor, wherein the DC-link capacitor may be arranged in the third unit electrically upstream of the joint DC/DC converter stage. Either the first unit or the second unit may be feeding the joint DC/DC converter of the third unit. Particularly, the DC/DC converter is configured to regulate the voltage and to charge the battery to the desired voltage level.

In other words, the AC charging system according to the invention may be described to comprise a car-pad module (CPM) and an on-board charger (OBC), wherein these two modules share some electric components. Preferably, the CPM comprises at the very least the coil, but may further comprise: (a) the second unit, or (b) the second and third unit, or (c) the first, second, and third unit, or (d) only the tuning circuit of the second unit. A controller for the CPM may be integrated into the third unit, allowing for more flexibility and cost reduction. This controller is termed “DC controller” herein as its main purpose is to control the DC/DC converter. This implies that said DC controller may be in the CPM or outside, i.e., for example in the OBC. An optional sensor in the CPM, i.e., preferably in the second unit, may provide location information, e.g., used to inform the DC controller about whether or not the electric vehicle is suitably positioned, i.e., whether or not the coils in the CPM and the ground-pad module (GPM) are suitably aligned. In case of a suitable alignment, the DC control unit may automatically initiate wireless charging of the high-voltage battery. Alternatively, charging may be initiated by a human operator, e.g., by communicating wirelessly with the DC control unit. For this, the CPM, in particular, the second unit, may comprise a receiver, e.g., using wireless communication technology such as WiFi or Bluetooth. Both sensor and receiver would each be connected to the DC controller. The DC controller may be located in the second unit or in the third unit, and regardless, it may be located in the CPM or in the OBC.

### BRIEF DESCRIPTION OF THE DRAWINGS

The inventive system is described below in more detail purely by way of example with the aid of concrete example embodiments illustrated schematically in the drawings, further advantages of the invention also being examined. Identical elements are labelled with the same reference numerals in the figures. In detail:

FIG. 1 shows a schematic depiction of a wired charging system according to prior art;

FIG. 2 shows a schematic depiction of a wireless charging system according to prior art;

FIG. 3 shows a schematic depiction of an embodiment of the invention; and

FIGS. 4-9 show schematic depictions of embodiments of the invention.

### DETAILED DESCRIPTION OF THE DRAWINGS

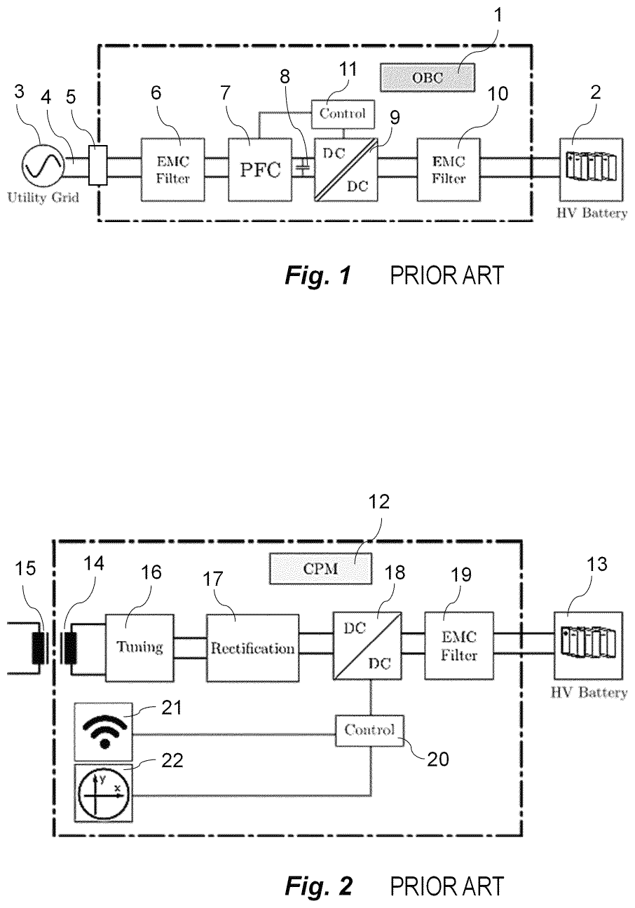

FIG. 1 shows a schematic illustration of a wired charging system 1 according to the state of the art. The wired charging system 1 is configured to charge a high-voltage (HV) battery 2 by drawing power from an alternating current (AC) utility grid 3 to which the system 1 is connected via a cable 4 plugged into the socket 5. The wired charging system 1 may also be termed on-board charger (OBC) and may be directly placed in a vehicle which also comprises the HV battery 2.

The example wired charging system 1 comprises a first electromagnetic compatibility (EMC) filter stage 6, e.g., configured for reducing a transfer of electromagnetic noise from the utility grid 3 to the remaining components of the wired charging system 1, and a power factor correction (PFC) stage 7 which outputs fixed direct current (DC) voltage and ensures a unity power factor. A subsequent capacitor 8 may be used smoothing the output provided by the PFC stage 7. The wired charging system 1 additionally comprises an isolated DC/DC converter 9 that regulates the voltage so as to charge the HV battery 2, and that provides galvanic isolation. A second EMC filter stage 10 follows the isolated DC/DC converter, which second EMC filter stage is connectable to the HV battery 2.

A controller 11 is also part of the wired charging system 1, which controller may be used for controlling operation of the PFC stage 7 and of the isolated DC/DC converter 9, e.g., by selecting the voltage of the output provided by the isolated DC/DC converter.

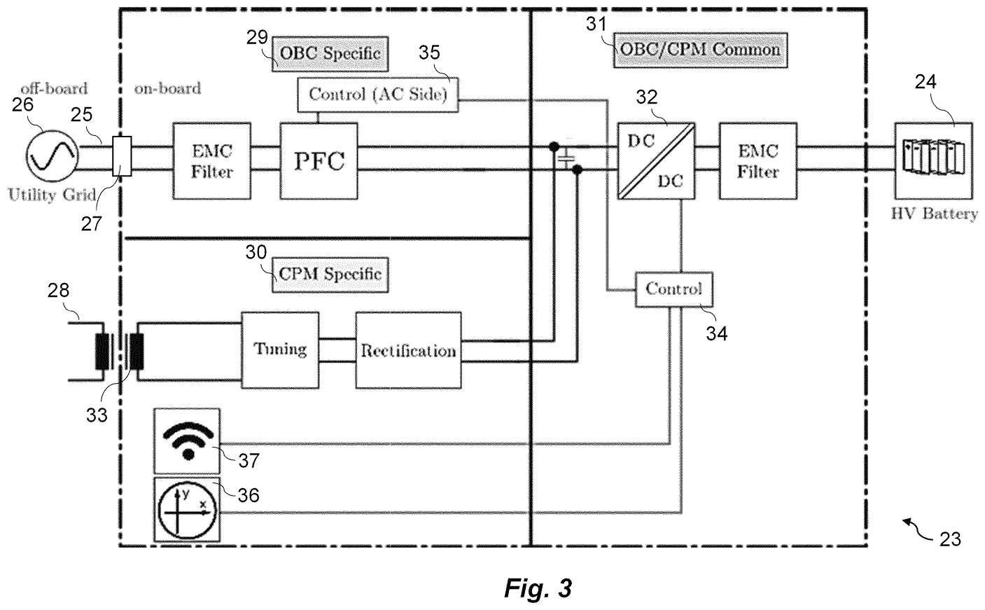

FIG. 2 shows a schematic illustration of a wireless charging system 12, also termed car-pad module (CPM), according to the state of the art, which CPM 12 may be placed in a vehicle with a HV battery 13. The CPM 12 wirelessly receives electric power, e.g., through induction using a coil 14, from a corresponding coil 15 comprised by an external module (GPM), also termed ground-pad module (GPM). Using a tuning circuit stage 16, the wireless charging system 12 may be tuned to a specific frequency, e.g., by connecting capacitances to the coil.

The wirelessly received electrical signal, being an AC signal, is subsequently rectified during a rectification stage 17, providing a DC signal. The DC signal provided by the rectification is subsequently converted and boosted by a DC/DC converter 18 to a voltage with specified power level, the DC/DC converter, e.g., being embodied as buck-boost converter. The DC/DC converter output is provided to an EMC filter 19, and the output of the EMC filter is used to charge the HV battery 13. The CPM 12 comprises a DC controller 20, which controller controls the charging process of the HV battery 3. The DC controller 20 is configured to receive charging management data and to control the DC/DC converter 18 based on the received charging management data. Charging management data may be provided by a wireless receiver 21, and/or the DC controller 20 may receive location information provided by a sensor 22, e.g., specifying the relative location between the coil 14 of the CPM 12 and a corresponding coil 15 in the GPM, wherein the two coils are used for wirelessly transmitting electrical power between the CPM and the CPM.

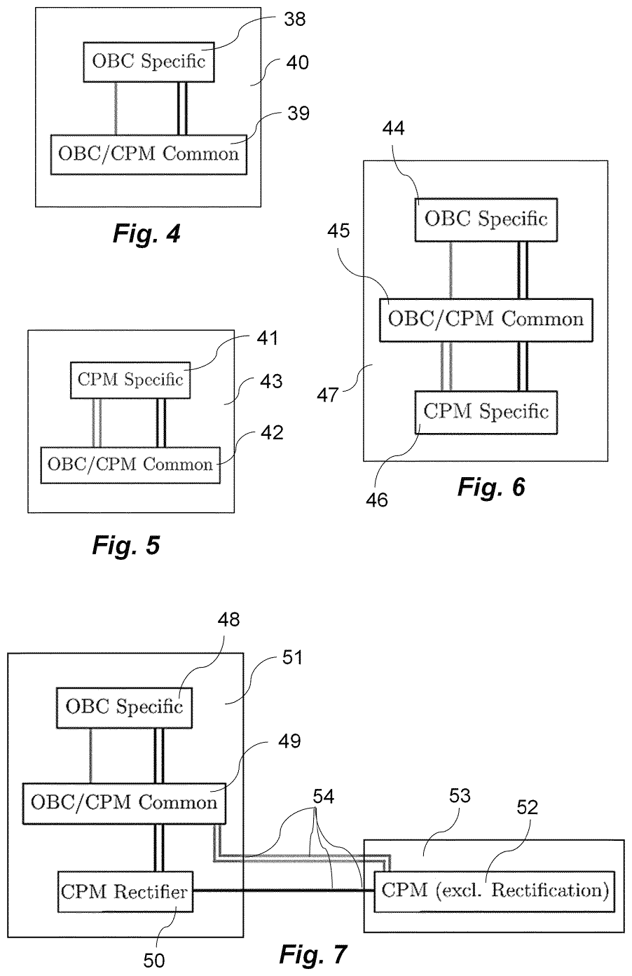

FIG. 3 shows a schematic view of an embodiment of the present invention. It can be seen right away that the amount of components used in this AC charging system 23 is smaller than the combined amount of components used in both the OBC 1 (FIG. 1) and the CPM 12 (FIG. 2).

The AC charging system 23 is capable of charging the HV battery 24 with electrical power via a cable 25 connecting a utility grid 26 with a socket 27 or wirelessly via a GPM 28. Because both charging modes needs to make use of similar or same components, the invention provides an integrated solution for them. With regard to the function and purpose of the single components in the first unit (OBC specific) 29 and the second unit (CPM specific) 30, it is referred to FIGS. 1 and 2. Now, the third unit (OBC/CPM common) 31 is the conceptual division with components that are used both with wire-based charging (first mode) and with wireless charging (second mode).

The DC/DC converter 32 is configured for converting direct current originating from electric power received via the socket 27 and for converting direct current originating from electric power received via the coil 33. Said DC/DC converter 32 is controlled with a DC controller 34, which is provided with input from the AC controller 35, from the sensor 36 and the receiver 37. From the constructional point of view, the DC controller 34 could also be “located” in the second unit 30, however, in this case there would need to be a direct interface between the OBC 29 and the CPM 30. The way it is shown, each the OBC 29 and the CPM 30 merely need to have an interface with the second unit 31 which interfaces the HV battery 24.

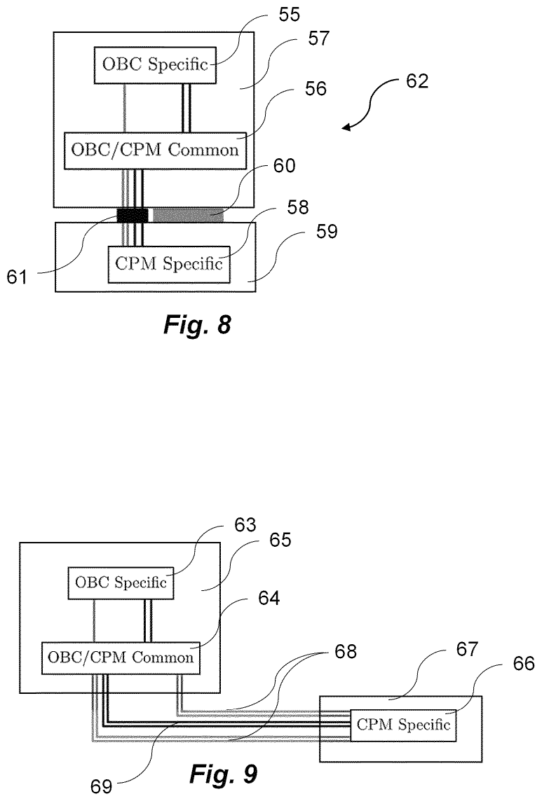

FIGS. 4 to 9 show examples of how the invention could be exploited.

FIG. 4 shows a first unit 38 and a third unit 39 as described herein forming a first module comprising, and surrounded by, a first housing 40. A second module (not shown) configured for cooperating with the first module forms a separate subject-matter and may comprise a second unit as described herein. Such second module then may be located underneath the vehicle together in one housing with the coil that is used for receiving the AC supplied by a GPM on the floor. The second module would then convert the AC into DC and supply it to the first module 40 via a wired connection, wherein the first module has respective interfaces for the DC as well as for the sensor data from the sensor (see numeral 36 in FIG. 3) and for the charging management data from the receiver (see numeral 37 in FIG. 3). The first housing 40 may comprise a socket or may be connectable to a socket. Example locations of such a first housing 40 may be close to the socket of the vehicle, or close to the HV battery.

As a fundamentally different embodiment, FIG. 5 shows a second unit 41 and a third unit 42 as described herein forming a first module comprising, and surrounded by, a first housing 43. A second module (not shown) configured for cooperating with the first module forms a separate subject-matter and may comprise a first unit as described herein. Such second module then may be located close to the socket of the vehicle that is used for receiving the AC supplied by a cable connected to the utility grid. The second module would then convert the AC into DC and supply it to the first module 43 via a wired connection, wherein the first module has respective interfaces for the DC as well as for AC control data from the AC controller (see numeral 35 in FIG. 3). The first housing 43 may comprise a coil or may be connectable to a coil. Example locations of such a first housing 43 may be underneath the vehicle next to or combined with the coil, or detached from the coil anywhere else suitable in the vehicle.

FIG. 6 shows a first unit 44, a second unit 45, and a third unit 46 as described herein comprised by one single housing 47. Such a single housing 47 may comprise or be connected with (in each case) (a) a coil and (b) a socket. Thus, possible locations of the single housing 47 may be close to the coil (underneath the vehicle) or close to the socket. However, since both power interfaces (a) and (b) may simply be connected to the single housing 47 via an extension wire, it may as well be located anywhere suitable in the vehicle.

FIG. 7 shows a first unit 48 and a third unit 49 as described herein as well as a rectifier 50 (formerly described as belonging to the second unit) being comprised by a first housing/module 51, wherein the rest 52 of a second unit as described herein is outsourced in a second housing/module 53. The two modules are connected by respective cables/interfaces 54. For example, such first housing 51 may be located close to the socket and such second housing 53 may be located close to the coil or combined with the coil, i.e., underneath the vehicle. Again, the first housing 51 may comprise or be connected with a socket, and the second housing 53 may comprise or be connected with a coil.

FIG. 8 shows a first unit 55 and a third unit 56 as described herein comprised by a first housing 57 and a second unit 58 as described herein encased in a second housing 59 which is attached to the first housing 57 via a cooling plate 60 that is configured to cool the two housings with respective cooling plate surfaces. All necessary connections are provided by interfaces 61. Such a housing/cooling combination (57+60+59=62) may comprise or be connected with (in each case) (a) a coil and (b) a socket. Thus, possible locations of the combination 61 may be close to the coil (underneath the vehicle) or close to the socket. However, since both power interfaces (a) and (b) may simply be connected to the combination 62 via an extension wire, it may as well be located anywhere suitable in the vehicle.

FIG. 9 shows a similar configuration as the one from FIG. 8, wherein the housings/modules are not adjacent to one another but may occupy different locations within the vehicle, but nevertheless share one coolant circuit that includes a first cooling plate (not shown) for the first module 65 and a second cooling plate (not shown) for the second module 67. The first module 65 houses a first unit 63 as described herein and a third unit 64 as described herein. The second module 67 houses a second unit 66 as described herein. Coolant for cooling the two cooling plates is circulating while visiting both modules 65 and 67 by flowing through respective cooling channels or cooling hoses 68. Wires 69 ensure the electrical connection and data connection between the modules 65 and 67. Again, the first housing 65 may comprise or be connected with a socket, and the second housing 67 may comprise or be connected with a coil.

Although the invention is illustrated above, partly with reference to some preferred embodiments, it must be understood that numerous modifications and combinations of different features of the embodiments can be made. All of these modifications lie within the scope of the appended claims.

1. An alternating current (AC) charging system for charging a high-voltage (HV) battery of a vehicle,
wherein the AC charging system comprises;
a socket configured to connect a cable and receive AC via the cable from a first external power supply, and
a coil configured to receive AC wirelessly from a second external power supply, wherein the AC charging system is configured to:
charge the HV battery in a first mode based on the alternating current received via the cable, and
charge the HV battery in a second mode based on alternating current wirelessly received via the coil,
wherein the AC charging system further comprises:
a first unit comprising at least one first electric component exclusively usable for charging in the first mode, the first unit connected to the socket,
a second unit comprising at least one second electric component exclusively usable for charging in the second mode, the second unit connected to the coil, and
a third unit comprising at least one third electric component usable for charging in the first mode and for charging in the second mode, the third unit connectable to the HV battery.

2. The AC charging system according to claim 1, wherein the first unit comprises a first electromagnetic compatibility (EMC) filter connected to the socket and configured to receive the AC from the socket.

3. The AC charging system according to claim 2, wherein the first unit comprises:
a power factor correction (PFC) configured to receive and convert AC filtered by the first EMC filter into direct current (DC), and
an AC controller configured to control the PFC.

4. The AC charging system according to claim 1, wherein the second unit comprises a tuning circuit configured to receive the AC from the coil.

5. The AC charging system according to claim 4, wherein the second unit comprises a rectifier configured to receive and convert the AC tuned by the tuning circuit into DC.

6. The AC charging system according to claim 1, wherein the second unit comprises a receiver configured to receive charging management data.

7. The AC charging system according to claim 1, wherein the second unit comprises a sensor configured to determine sensor data relating to a magnetic field detected at the coil.

8. The AC charging system according at least to claim 3, wherein the third unit comprises a DC/DC converter configured to receive DC from the PFC and from a rectifier, the rectifier configured to receive and convert the AC as tuned by a tuning circuit from the coil into DC.

9. The AC charging system according at least to claim 8, wherein the third unit comprises a second EMC filter configured to receive the DC converted by the DC/DC converter, filter the converted DC for supply to the HV battery.

10. The AC charging system according at least to claim 3, wherein the third unit comprises a DC controller connected to a receiver, a sensor, a DC/DC converter, and to the AC controller, the DC controller configured to control the DC/DC converter based on at least one of charging management data received by the receiver, sensor data received by the sensor relating to a magnetic field detected at the coil, and AC controller data received from the AC controller.

11. The AC charging system according to claim 1, wherein a single housing comprises the first unit, the second unit, and the third unit.

12. The AC charging system according to claim 1, wherein a first housing comprises the first unit and the third unit, and a second housing comprises the second unit, wherein the AC charging system further comprises one of:
a cooling unit with a cooling plate having a first cooling plate surface and a second cooling plate surface, the first cooling plate surface abutting the first housing and the second cooling plate surface abutting the second housing, and
a cooling unit with a first cooling plate and a second cooling plate, the first cooling plate abutting the first housing and the second cooling plate abutting the second housing, the first cooling plate and the second cooling plate sharing a single coolant circuit.

13. The AC charging system according to claim 5, wherein a first housing comprises the first unit, the second unit, and the rectifier from the third unit, and a second housing comprises the third unit except for the rectifier.

14. A module for an alternating current (AC) charging system for charging a high-voltage (HV) battery of a vehicle,
wherein the module comprises:
a first electromagnetic compatibility (EMC) filter configured to receive the AC from a socket,
a power factor correction (PFC) configured to receive and convert AC filtered by the first EMC filter to direct current (DC),
an AC controller configured to control the PFC,
a first interface,
a DC/DC converter configured to receive DC from the PFC and from the first interface,
a second interface,
a DC controller configured to:
receive sensor data and charging management data from the second interface,
receive AC controller data from the AC controller, and
control the DC/DC converter based on at least one of the charging management data, the sensor data, and the AC controller data,
a second EMC filter configured to receive DC converted by the DC/DC converter, and
a third interface configured to receive DC filtered by the second EMC for supply to the HV battery.

15. A module for an alternating current (AC) charging system for charging a high-voltage (HV) battery of a vehicle,
wherein the module comprises:
a tuning circuit configured to receive AC from a coil,
a rectifier configured to receive AC tuned by the tuning circuit,
a receiver configured to receive charging management data,
a sensor configured to determine sensor data relating to a magnetic field detected at the coil,
a first interface,
a direct current/direct current (DC/DC) converter configured to receive DC from the rectifier and from the first interface,
a second interface,
a DC controller configured to:
receive the sensor data and the charging management data,
receive AC controller data from the second interface, and
control the DC/DC converter based on at least one of the charging management data, the sensor data, and the AC controller data,
an electromagnetic compatibility (EMC) filter configured to receive DC converted by the DC/DC converter, and
a third interface configured to receive DC filtered by the EMC for supply to the HV battery.
